(19) United States
(12) Patent Application Publication
(10) Pub. No.: US 2016/0368077 A1
(43) Pub. Date: Dec. 22, 2016

(54) SURFACE PROCESSING IN ADDITIVE MANUFACTURING WITH LASER AND GAS FLOW

(71) Applicants: Bharath Swaminathan, San Jose, CA (US); Eric Ng, Mountain View, CA (US); Nag B. Patibandla, Pleasanton, CA (US); Hou T. Ng, Campbell, CA (US); Ajey M. Joshi, San Jose, CA (US); Ashavani Kumar, Sunnyvale, CA (US); Bernard Frey, Livermore, CA (US); Kasiraman Krishnan, Milpitas, CA (US)

(72) Inventors: Bharath Swaminathan, San Jose, CA (US); Eric Ng, Mountain View, CA (US); Nag B. Patibandla, Pleasanton, CA (US); Hou T. Ng, Campbell, CA (US); Ajey M. Joshi, San Jose, CA (US); Ashavani Kumar, Sunnyvale, CA (US); Bernard Frey, Livermore, CA (US); Kasiraman Krishnan, Milpitas, CA (US)

(21) Appl. No.: 15/186,247

(22) Filed: Jun. 17, 2016

Related U.S. Application Data
(60) Provisional application No. 62/182,207, filed on Jun. 19, 2015.

(51) Int. Cl. B23K 10/00; H01J 37/305; H05H 1/30; B25J 9/00; B23K 26/36

(52) U.S. Cl. CPC B23K 10/00; B25J 9/0096; B23K 26/36; H05H 1/30; H01J 37/3056; B33Y 40/00

(57) ABSTRACT

An apparatus for surface modification includes a support to hold a workpiece, a plasma source to generate a plasma in a localized region that is smaller than the workpiece, and a six-axis robot to manipulate relative positioning of the workpiece and the plasma source. The six-axis robot is coupled to at least one of the support and the plasma source.

### CROSS-REFERENCE TO RELATED APPLICATIONS

This application claims priority to U.S. application Ser. No. 62/182,207, filed on Jun. 19, 2016, which is incorporated by reference in its entirety.

### TECHNICAL FIELD

This present specification relates to additive manufacturing, also known as 3D printing.

### BACKGROUND

Additive manufacturing (AM), also known as solid freeform fabrication or 3D printing, refers to a manufacturing process where three-dimensional objects are built up from raw material (generally powders, liquids, suspensions, or molten solids) in a series of two-dimensional layers or cross-sections. In contrast, traditional machining techniques involve subtractive processes and produce objects that are cut out of a stock material such as a block of wood or metal.

A variety of additive processes can be used in additive manufacturing. The various processes differ in the way layers are deposited to create the finished objects and in the materials that are compatible for use in each process. Some methods melt or soften material to produce layers, e.g., selective laser melting (SLM) or direct metal laser sintering (DMLS), selective laser sintering (SLS), fused deposition modeling (FDM), while others cure liquid materials using different technologies, e.g. stereolithography (SLA).

Sintering is a process of fusing small grains, e.g., powders, to create objects. Sintering usually involves heating a powder. When a powdered material is heated to a sufficient temperature in a sintering process, the atoms in the powder particles diffuse across the boundaries of the particles, fusing the particles together to form a solid piece. In contrast to melting, the powder used in sintering need not reach a liquid phase. As the sintering temperature does not have to reach the melting point of the material, sintering is often used for materials with high melting points such as, for example, tungsten and molybdenum.

Both sintering and melting can be used in additive manufacturing. The material being used determines which process occurs. An amorphous solid, such as acrylonitrile butadiene styrene (ABS), is actually a supercooled viscous liquid, and does not actually melt; as melting involves a phase transition from a solid to a liquid state. Thus, SLS can be used with ABS, and SLM can be used for crystalline and semi-crystalline materials such as nylon and metals, which have a discrete melting/freezing temperature and undergo melting during the SLM process.

Conventional systems that use a laser beam as the energy source for sintering or melting a powdered material typically direct the laser beam on a selected point in a layer of the powdered material and selectively raster scan the laser beam to locations across the layer. Once all the selected locations on the first layer are sintered or melted, a new layer of powdered material is deposited on top of the completed layer and the process is repeated layer by layer until the desired object is produced. An electron beam can also be used as the energy source to cause sintering or melting in a material. Once again, the electron beam is raster scanned across the layer to complete the processing of a particular layer.

### SUMMARY

It would be desirable to manufacture a part from a workpiece generated by a 3D printing process and to further modify the workpiece to include additional geometric features of higher resolution than the geometric features produced as part of the 3D printing process. The part, for example, can include both low-resolution and high-resolution features, and a combination of the 3D printing process and a post-processing operation can achieve both types of features. In some cases, the part can include simple geometries achievable by the 3D printing process and complex geometries that the post-processing operation incorporates into the workpiece.

The modification to the workpiece after the 3D printing process can include modifications from a point power source, an area power source, or combinations thereof that apply power to specific portions of the workpiece to incorporate into the workpiece high-resolution features of the part. The point power sources can add heat to small portions of the workpiece to modify the workpiece, and the area power sources can apply ionized gas or plasma that can add power to a localized portion of the workpiece. In some cases, the plasma can further be used to produce chemical modifications to a surface of the workpiece. As part of the process of modifying the workpiece, a sensing system can detect when the point power source and/or the area power source have achieved the features.

In one aspect, an apparatus for surface modification includes a support to hold a workpiece, a plasma source to generate a plasma in a localized region that is smaller than the workpiece, and a six-axis robot to manipulate relative positioning of the workpiece and the plasma source. The six-axis robot is coupled to at least one of the support and the plasma source.

Implementations can include one or more of the following features. The apparatus can include a controller coupled to the robot and the plasma source. The controller can be configured to coordinate operation of the robot and the plasma source to cause ions from the plasma to impinge only a portion of an exposed surface of the workpiece.

The apparatus can include a vacuum chamber, and the support, the plasma source and the robot can be positioned in the vacuum chamber. Additionally or alternatively, the apparatus can include a laser positioned to generate a laser beam that passes through the localized region. A beam spot of the laser beam on an exposed surface of the workpiece can be smaller than a portion of the workpiece impinged by the plasma.

In some examples, the apparatus can include a focused ion beam system positioned to generate a focused ion beam that passes through the localized region. A beam spot of the focused ion beam on an exposed surface of the workpiece can be smaller than a portion of the workpiece impinged by the plasma.

The plasma source of the apparatus can include a tube, a gas source to inject a gas into the tube, a first radio frequency (RF) power source, and a first plurality of conductive coils surrounding the tube and coupled to the first RF power source. In some cases, the apparatus can include a second radio frequency (RF) power source. A second plurality of conductive coils can be coupled to the second RF power source. The second plurality of coils can be positioned to surround a volume in which the plasma is emitted from the tube. In some implementations, a controller can be configured to cause the robot to position the workpiece such that the volume is between the workpiece and the tube. The first and second plurality of coils can be oriented along parallel axes. In some cases, the apparatus can include a third radio frequency (RF) power source coupled to the support.

Another aspect of the systems and methods described herein includes a method of surface modification. The method includes generating a plasma adjacent to a workpiece in a localized region that is smaller than the workpiece such that ions from the plasma impinges only a portion of an exposed surface of the workpiece.

In some cases, the ions from the plasma can be sputtered onto the portion of the exposed surface. Ions from the plasma can etch the portion of the exposed surface.

In some examples, the method can include reactively sputtering onto the portion of the exposed surface. The method can include impinging the portion of the exposed surface with a laser beam simultaneous with generating the plasma. The laser beam can heat or be configured to heat the exposed surface without removing material from the exposed surface. The laser beam can ablate or be configured to ablate material from the exposed surface.

The method can further include constraining the plasma with a coil positioned to surround a volume between a plasma source and the workpiece. The method can include milling the portion of the exposed surface with a focused ion beam simultaneous with generating the plasma. The method can additionally or alternatively include controllably positioning the workpiece relative to the plasma source with a six-axis robot.

A further aspect of the systems and methods described herein includes a manufacturing system. The manufacturing system includes a 3D printer configured to fabricate a workpiece and an apparatus for surface modification. The apparatus includes a support to hold a workpiece, a plasma source to generate a plasma in a localized region that is smaller than the workpiece, and a six-axis robot coupled to at least one of the support and the plasma source to manipulate relative positioning of the workpiece and the plasma source. The manufacturing system further includes a transport system to move the workpiece from the additive manufacturing system to the support in the apparatus for surface modification.

Another aspect of the systems and methods described herein includes a method of manufacturing a part. The method includes fabricating a part by 3D printing, and applying ions to a selected portion of an exposed surface of the fabricated part by generating a plasma adjacent to a workpiece in a localized region that is smaller than the workpiece.

Implementations can provide one or more of the following advantages. A workpiece can be easily modified to include complex surface properties and geometries. A post-processing system can modify the complex surface properties to have a hardness or roughness within predetermined ranges. For example, a part may be designed to include localized portions that have a predetermined roughness and hardness that 3D printing process may not be able to achieve. The part may be designed to have detailed geometries, such as etched geometry, in localized portions of the workpiece that the 3D printing process may not be able to achieve. The 3D printing may further cause deformations to or leave residue on localized portions of the workpiece that the post-processing system can easily clean. The post-processing system can remove, clean, or otherwise modify the localized portions while preventing other portions of the workpiece from being modified. The post-processing system can localize the modifications to different sized portions using point power sources directed to points along a surface of the workpiece or area power sources directed to areas along the surface of the workpiece.

The details of one or more implementations are set forth in the accompanying drawings and the description below. Other aspects, features, and advantages will be apparent from the description and drawings, and from the claims.

### DESCRIPTION OF DRAWINGS

FIG. 1 is a block diagram of a part manufacturing system.

FIG. 2 is a schematic side view of a post-processing system of the part manufacturing system of FIG. 1.

FIG. 3 is a schematic view of a robot.

FIG. 4 is a block diagram of a control system for the post-processing system of FIG. 2.

Like reference symbols in the various drawings indicate like elements.

### DETAILED DESCRIPTION

A CAD system can generate instructions to fabricate a part that includes both gross features (e.g., low-resolution geometries and features) and detailed features (e.g., high-resolution geometries and features). In some cases, a workpiece fabrication system, such as a 3D printing system, may be suitable to fabricate a workpiece having the gross geometry using a 3D printing process. Thus, the workpiece fabrication system can generate the workpiece using the instructions indicative of the gross geometry of the part. After the workpiece has been initially fabricated, the workpiece can undergo further post-fabrication processes to achieve the detailed geometry and features that were not incorporated as part of the 3D process of the 3D printing system. The post-fabrication processes can include independently controlled processes to modify both large and small areas of the workpiece to include the detailed features of the part. Using the instructions from the CAD system, a post-processing system, as described herein, can further modify the workpiece to incorporate the detailed geometries and features of the part.

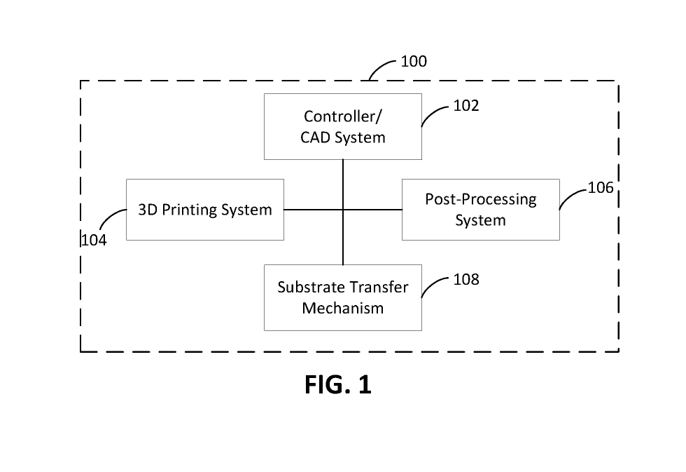

A manufacturing system to manufacture a part can include mechanisms, modules, and other systems to design, fabricate, and post-process a workpiece that becomes the part. FIG. 1 shows a block diagram of a part manufacturing system 100 including a controller 102, a 3D printing system 104, a post-processing system 106, and a substrate transfer mechanism 108. The controller 102 communicates with the 3D printing system 104, the post-processing system 106, and the substrate transfer mechanism 108 to facilitate manufacture of the part. Each of the 3D printing system 104, the post-processing system 106, and the substrate transfer mechanism 108 can include a controller that receives instructions from the controller 102 and executes operations of the respective system.

The controller 102 includes a computer aided design (CAD) system that generates instructions can be usable by each of the 3D printing system 104, the post-processing system 106, and the substrate transfer mechanism 108 to manufacture the part. The 3D printing system 104 uses instructions received from the controller 102 to implement a 3D printing process to fabricate the workpiece. The 3D printing system 104 can execute an appropriate 3D printing process—such as, for example, selective laser melting (SLM) or direct metal laser sintering (DMLS), selective laser sintering (SLS), fused deposition modeling (FDM), and stereolithography (SLA)—to create the workpiece.

After the 3D printing system creates the workpiece, the workpiece can include low-resolution features and geometries indicated in the instructions generated by the CAD system of the controller. For example, the workpiece fabricated by the 3D printing system 104 can include features having a resolution between, for example, 10 micrometers to 50 micrometers, 50 micrometers and 100 micrometers, or 100 micrometers to 1 mm. As a result, using the instructions from the CAD system, the 3D printing system 104 can generate additional instructions to control individual systems (e.g., power systems, robot systems, valves, and other systems) of the 3D printing system 104 to create the workpiece. The controller 102 can operate various components of the 3D printing system 104 including, for example, a dispenser, a drive system, a laser system, power sources, a gas delivery system, and other appropriate components to operate the 3D printing system 104.

The post-processing system 106 uses instructions received from the controller 102 to analyze and process the workpiece so that the workpiece can include the high-resolution features of the part described in the instructions generated by the CAD system. The high-resolution features can include micro-scale roughnesses. Film thicknesses can also be deposited at depths of between, for example, 0 to 500 angstroms. For example, the post-processing system 106 can process a surface of the workpiece so that the surface includes features of the final part that the 3D printing process implemented by the 3D printing system 104 may not have incorporated into the workpiece. In some cases, the post-processing system 106 can reactively sputter and selectively heat localized portions of the surface of the workpiece to modify surface texture, hardness and other material surface properties.

The post-processing system 106 can include power sources that direct power to localized regions above the workpiece as small as a few millimeters in diameter (e.g., using a point power source) or to localized regions above the workpiece as large as a few centimeters in diameter (e.g., using an area power source). A point power source can be, for example, a laser that emits a laser beam onto a small portion of the workpiece to add heat to the part. An area power source can be, for example, a plasma delivery system that emits plasma from a plasma source in the localized region above the workpiece. Using the area power sources and point power sources, the post-processing system 106 can modify localized portions of an exposed surface of the workpiece. The workpiece can be fabricated using an additive manufacturing process (e.g., as described with respect to the 3D printing system 104) and have improved resolution using subtractive manufacturing processes associated with the post-processing system 106.

From the instructions generated from the CAD system, the post-processing system 106 can control the power sources to achieve various modifications to the workpiece. For example, the plasma delivery system of the post-processing system 106 can emit plasma at different fluxes to etch the surface of the workpiece to have a controllable roughness or hardness. In another example, the laser can operate in several modes, including a low-power mode to heat a part, a medium-power mode to remove minor material deformations that may have occurred during the 3D printing process (e.g., flash, tool marks), and a high-power mode to vaporize or etch the localized portion of the workpiece. The controller of the post-processing system 106 can control the frequency and the power level of the laser depending on the feature that the CAD instructions indicate. For example, if the CAD instructions indicate an etched feature in the part, the post-processing system 106 can increase the power level of the laser so that the laser can etch the localized portions of the workpiece.

A sensing system of the post-processing system 106 can detect properties of the surface of the workpiece and hence monitor processes implemented by the post-processing system 106. For example, the sensing system can detect deformations in the workpiece that may have been caused by, for example, the 3D printing process. In one implementation, if the post-processing system 106 detects flash, the controller of the post-processing system 106 can transmit instructions to the laser to decrease the power level and/or the frequency of the laser so that the laser can clean the flash without causing damage to the rest of the workpiece.

The post-processing system 106 can also operate in various modes depending on the material (e.g., the type of metal, plastic, or ceramic) from which the workpiece is formed during the 3D printing process of the 3D printing system 104. In some cases, the workpiece can be made of metal, ceramics, or plastic. Examples of metallic particles include titanium, stainless steel, nickel, cobalt, chromium, vanadium and various alloys of these metals. Examples of ceramic materials include metal oxide, such as ceria, alumina, silica, aluminum nitride, silicon nitride, silicon carbide, or a combination of these materials. Examples of plastics can include ABS, nylon, Ultem, polyurethane, acrylate, epoxy, polyetherimide, or polyamides.

In some cases, the sensing system detects the material of the workpiece, and the post-processing system 106 subsequently selects a mode that modulates, for example, an amount of power for the laser and/or plasma delivery system depending on the material detected. In other cases, the post-processing system 106 can include a user input for the type of material of the workpiece.

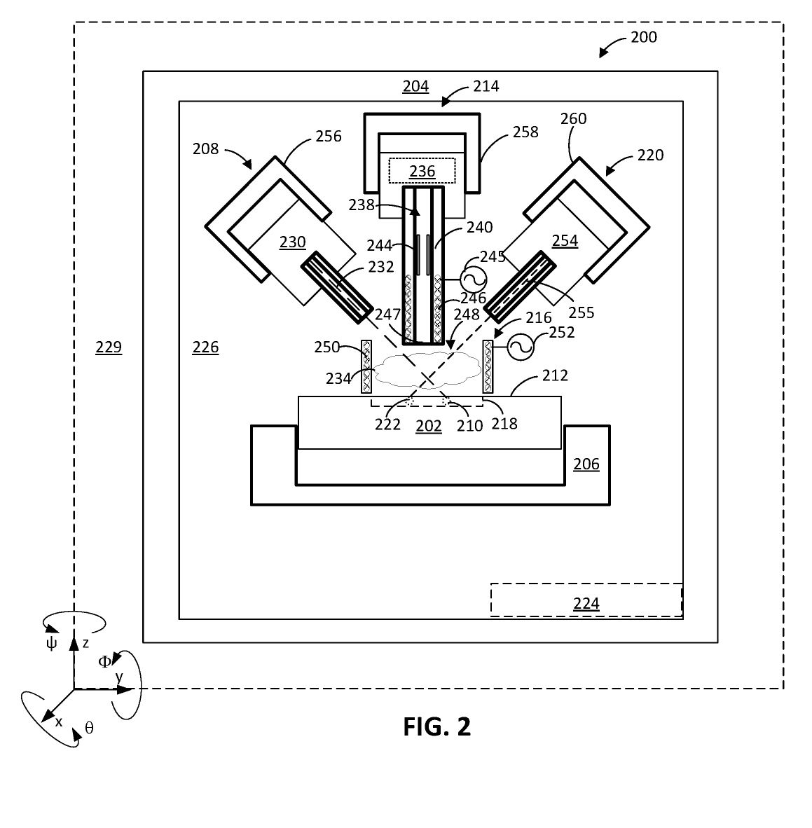

An exemplary post-processing system 200 (e.g., the post-processing system 106 of FIG. 1), as shown in FIG. 2, includes several systems to process, manipulate, and monitor a workpiece 202. In some implementations, the workpiece 202 was fabricated using a 3D printing system (e.g., the 3D printing system 104 of FIG. 1) and was moved from the 3D printing system to the post-processing system 200 using a substrate transfer mechanism (e.g., the substrate transfer mechanism 108 of FIG. 1). The post-processing system 200 includes a housing 204 that encloses a workpiece robot 206 to manipulate the workpiece 202; a sensing system 208 to sense attributes of a small portion 210 on a surface 212 of the workpiece 202; a plasma delivery system 214 and a plasma confinement system 216 to modify a localized portion 218 of the surface 212; and a laser finishing system 220 to modify a small portion 222 on the surface 212. The post-processing system 106 can include a controller 224 to receive instructions from a CAD system (e.g., the controller 102 of FIG. 1) or other external system and deliver instructions to each of the systems of the post-processing system 200. Optionally, one or more of the sensing system 208, plasma systems 214/216 or laser finishing system 220 can be omitted.

The housing 204 defines an interior chamber 226 and separates the interior chamber from an outside environment 229 to create an interior environment within the interior chamber 226 that reduces defects during post-processing of the workpiece 202. The housing 204 can allow a vacuum environment, e.g., less than 1 Torr or between 0.0001 Torr to 1 Torr, to be maintained in the chamber 226. The pressure maintained within the vacuum environment can affect plasma density. Thus, the interior chamber 226 can be a vacuum chamber within which the workpiece robot 206, the sensing system 208, the plasma delivery system 214, the plasma confinement system 216, and the laser finishing system 220 are contained and positioned. In some cases, the chamber 226 can include a substantially pure gas, e.g., a gas that has been filtered to remove particulates. In other cases, the chamber can be vented to atmosphere. The vacuum environment or the filtered gas can reduce a likelihood of defects occurring during use of, for example, the sensing system 208, the plasma delivery system 214, and the laser finishing system 220.

When the workpiece 202 is placed into the post-processing system 200 for processing (e.g., by the substrate transfer mechanism 108 of FIG. 1), the workpiece robot 206 can serve as a support to receive, hold, and manipulate the workpiece 202. The workpiece robot 206 can receive instructions from the controller 224 to translate or rotate the workpiece 202 within the interior chamber 226. The workpiece robot 206 is a six-axis robot and can move the workpiece 202 along or rotate the workpiece 202 about any axis (e.g., x-axis, y-axis, and z-axis). The workpiece robot 206 can move in an x-direction, y-direction, and z-direction and can rotate in a θ-direction, a Φ-direction, and ψ-direction. The workpiece robot 206 can thus move or rotate the workpiece 202 relative to each of the sensing system 208, the plasma delivery system 214, and the laser finishing system 220.

The sensing system 208 senses attributes of the small portion 210 on the surface 212 of the workpiece 202. The sensing system 208 includes an x-ray photoelectron spectrometer (XPS) 228 that emits a beam 232 of x-rays toward the small portion 210 of the workpiece and detects electrons that escape from the small portion 210 due to the x-rays. The small portion 210 can be a beam spot of the beam 232 as the beam 232 contacts the surface 212 of the workpiece 202. The small portion 210 can have an area, e.g., defined by a circle or ellipse, in which the largest dimension is between, for example, 10 micrometers and 500 micrometers, 500 micrometers and 5 mm, and 10 mm and 50 mm. The XPS 228 can detect a kinetic energy and a quantity of electrons escaping from the small portion 210 and can determine material characteristics based on the kinetic energy and quantity. For example, the XPS 228 can determine chemical composition of the small portion 210 and/or material defects and/or contaminants within the small portion 210. In some cases, the XPS 228 can be configured to determine chemical composition of a depth profile the workpiece 202. In some cases, the XPS 228 can scan the surface 212 of the workpiece 202 and determine element and chemical composition of a line profile of the surface 212 of the workpiece 202.

While the sensing system 208 has been described to include the XPS 228 to determine surface features of the workpiece 202, in some implementations, the sensing system 208 can include other sensors and detection equipment. For example, the sensing system 208 can detect roughness, surface finish, or other surface features using an interferometer, confocal microscope, or other appropriate surface detection system. The sensing system 208 may also include an optical temperature sensor to determine a temperature of the small portion 210 of the workpiece 202. In some cases, the sensing system 208 can include several temperature sensors that monitor temperatures at various points along the surface 212 of the workpiece 202.

The plasma delivery system 214 and the plasma confinement system 216 can cooperate to modify the localized portion 218 of the surface 212 of the workpiece 202 using plasma 234 and to prevent portions of the surface 212 outside of the localized portion 218 from being modified. Depending on the processing conditions, ions from the plasma delivery system 214 can bombard the localized portion 218 to modify the surface properties. For example, the ions can cause a chemical reaction on the surface 212, be implanted into the surface 212, or cause sputtering of material from the surface 212. The ions can also cause sintering of material particles of the surface 212. For example, the ions can directed to powders disposed on the surface such that the powders are heated and sintered to form solid material.

The plasma delivery system 214 functions as a plasma source and can thus generate the plasma 234 above a localized region that is smaller than the workpiece 202. The plasma delivery system 214 includes a gas source 236 that supplies gas through a hollow interior 238 defined by a tube or conduit 240. Examples of gases supplied by the gas source 236 can include nitrogen, argon, helium, oxygen, and titanium fluoride, TiCl4, H2—He mixtures. The plasma delivery system 214 can include valves that are controlled by the controller 224 for the release of gases from the gas source 236 into the hollow interior 238. When the plasma 234 is released from the plasma delivery system 214, the plasma 234 is released into the localized region and can produce modifications to the localized portion 218 on the surface 212 of the workpiece 202.

Gas flowing through the plasma delivery system 214 becomes ionized as the gas passes through the hollow interior 238 of the conduit 240, thus forming the plasma 234. Plasma (e.g., the plasma 234) is an electrically neutral medium of positive and negative particles (i.e. the overall charge of the plasma is roughly zero). For example, when nitrogen gas is supplied from the gas source 236, the gas becomes ionized, thus producing N₂⁺ or N⁺. In general, applying two differentially charged opposing electrodes can cause gas supplied from the gas source 236 to form the plasma 234. In FIG. 2, when gas is supplied from the gas source 236 into the hollow interior 238, an alternating current (AC) power source (not shown) can transmit current to an electrode 244 positioned within the hollow interior 238. The hollow interior 238 further houses a counter-electrode that cooperates with the charged electrode 244 to generate an electric field within the hollow interior 238. The counter-electrode can be floating or connected to ground. The conduit 240 can be formed of a dielectric material to contain the electric field within the hollow interior 238. The electric field generated within the hollow interior 238 by the electrode 244 and the counter-electrode ionizes the gas flowing from the gas source 236, thus producing the plasma 234.

While the electrode 244 and the counter-electrode have been described to produce the plasma 234 within the hollow interior 238 of the conduit 240, in some implementations, the plasma 234 is generated as neutral gas particles exit the conduit 240. The workpiece 202 can be placed on a platen that is, for example, attached to or is part of the workpiece robot 206. For example, the platen can be the flat surface of an end-effector of the robot 206. An AC power source may be operable with the platen to charge the platen, and another AC power source may be operable with the conduit 240 (e.g., an inner surface toward the end 247 of the conduit 240 that serves as an electrode). The AC power sources can each transmit different radio-frequency drive voltages to the conduit 240 and the platen. In this case, the conduit 240 and the platen cooperate to generate the electric field to ionize the gas particles. The platen thus serves to support the workpiece 202 and to ionize the gas.

In some implementations, the end 247 can include a nozzle configured to accelerate flow of the gas as it exits the end 247 of the conduit 240. The nozzle can be configured to induce supersonic flow of the gas the ions. For example, the nozzle can be a de Laval nozzle, convergent-divergent nozzle, CD nozzle, or con-di nozzle. In some implementations, the de Laval nozzle can be a tube that is pinched in the middle to have a carefully balanced, asymmetric hourglass-shape. The nozzle can be used to accelerate a particle beam, for example, of ions passing through it to obtain a larger axial velocity. In this way, the kinetic energy of the particle beam causes removal of material from exposed portions of the surface 212 of the workpiece 202. The flow of the plasma 234 through the nozzle can be between, for example, 0 and 200 standard cubic centimeters (sccm).

In some implementations, the counter-electrode can be connected to a separate AC power source that charges the counter-electrode so that the electrode 244 and the counter-electrode have opposite charges. A higher radiofrequency drive voltage can be applied to the electrode 244 to control a flux of the ions in the plasma 234 while a lower radio frequency drive voltage applied to the counter-electrode can control an energy of the ions in the plasma. The controller 224 can adjust the radiofrequency voltages of the electrode 244 and the counter-electrode to control the energy or the flux of the ions.

An inductive coil 246 can be charged to accelerate plasma particles through the hollow interior 238 of the conduit 240 so that the plasma 234 can be dispensed into the localized region above the workpiece 202. The inductive coil 246 surround the hollow interior 238 of the conduit 240. An AC power source 245 may transmit radiofrequency current to the inductive coil 246 such that the inductive coil 246 generates a magnetic field within the hollow interior 238. Because the particles of the plasma 234 are ionized, the magnetic field couples with the particles and can cause the particles to accelerate in the direction of the magnetic field. The controller 224 can control the amount of acceleration imparted to the particles of the plasma 234 by adjusting the magnetic field generated by the inductive coil. The controller 224 can transmit instructions to the power source 245 to transmit the radiofrequency drive voltage to the inductive coil 246 and further adjust an amount of power or a frequency of the drive voltage. In this example, the magnetic field causes the ionized particles of the plasma 234 to accelerate toward an end 247 of the conduit 240 so that the plasma 234 can exit the conduit 240 into the localized region.

When the plasma 234 exits the plasma delivery system 214, the plasma 234 can be contained within a volume 248 overlying the localized region using the plasma confinement system 216. The plasma confinement system 216 includes inductive coils 250 connected to an AC power source 252 that can transmit a radiofrequency drive voltage to the inductive coils 250. The inductive coils 250 are positioned to surround the volume 248 in which the plasma 234 is emitted from the hollow interior 238 of the conduit 240. The inductive coils 250, when charged by the AC power source 252, can generate a magnetic field that serves to contain the plasma 234 within the volume 248 overlying the localized region. As a result, the plasma 234 does not affect the surface 212 of the workpiece 202 that is outside of the localized portion 218 as those portions of the surface 212 are not exposed to the plasma. The controller 224 can control an amount of power delivered by the AC power source 252 to the inductive coils 250 to modulate the size of the volume 248 and thereby the size of the area of the localized portion 218 of the workpiece 202 covered by the plasma 234. The controller 224 can be configured to control the inductive coils 250 such that the inductive coils 250 drive the ions of the plasma 234 by tuning the electromagnetic field generated by the inductive coils 250. The controller can adjust radiofrequencies of the AC power source 252 to drive the inductive coils 250. Alternately or additionally, the inductive coils 250 can also re-sputter deposited materials or materials of the workpiece 202 to produce stoichiometric alloyed compositions.

The inductive coils 250 can be positioned with the conduit 240 positioned at or near the center of the localized region. In some implementations, the inductive coils 250 can be mechanically fixed relative to the conduit 240. In some implementations, the inductive coils 250 are movable along the axis of the conduit 240, but are fixed laterally (perpendicular to the axis).

The plasma 234, when confined within the volume 248 adjacent the workpiece 202 along the localized region above the localized portion 218, impinges exposed portions of the surface 212 of the localized portion 218. The ions of the plasma 234 can thus cause chemical reactions to occur on the surface 212 of the localized portion 218. The chemical reactions can adjust a surface roughness of the localized portion 218 between, for example, 1 micrometer to 20 micrometers, 0.5 micrometers to 50 micrometers, or other appropriate ranges. Surface hardness depth can depend on the material of the workpiece 202 and the type of plasma treatment process used, such as, for example nitridation, anodization, and other processes. For example, nitridation can adjust a surface hardness depth of the localized portion 218 between, for example, 15 micrometers to 500 micrometers.

Other properties that can be locally modified using the plasma 234 include metal density and mechanical properties such as, for example, yield strength, fracture toughness, and resilience. The plasma 234 can further remove material from the localized portion 218, thus causing the localized portion 218 to have a lower surface roughness than the other portions of the surface 212. The plasma 234 thus impinges only a portion of an exposed surface of the workpiece 202, for example, the localized portion 218 of the workpiece 202.

Adjusting a density of the ions striking the localized portion 218 can adjust the surface roughness imparted to the localized portion 218. For example, adjusting the magnitude or frequency of radiofrequency drive voltages transmitted to each of the electrode and the counter-electrode can adjust the flux of the plasma 234 and hence the density of the ions striking the localized portion 218. In one example, the flux of the plasma 234 can be decreased such that fewer ions strike the surface of the fused feed material, causing irregularities on the surface that are spaced further apart and increasing the surface roughness of the localized portion 218. As described herein, the controller 224 can transmit instructions to the power sources associated with the inductive coil 246, the electrode 244, and the counter-electrode to adjust the flux of the ions in the plasma 234.

In some implementations, the process executed by the plasma delivery system 214 emitting the plasma 234 into the localized region above the localized portion 218 can further adjust other properties of the localized portion 218, such as, for example, hardness, grain size, crystallographic orientation. The plasma can further be used for processes to cause, for example, nitridation to modify hardness, passivation to protect parts from corrosive environments, and anodization. In some cases, the plasma delivery system 214 can dispense the plasma 234 to execute an electropolishing process to seal surfaces of the workpiece or to make surfaces reflective to reduce outgassing in vacuum and ultra-purity systems. The plasma delivery system 214 can also use the ions of the plasma 234 to etch the localized portion 218 of the workpiece 202. The plasma delivery system 214 can alternatively or additionally achieve surface texturing by plasma or arc spray. The plasma 234 can also add heat and sinter powdered materials around the localized portion 218 of the workpiece 202. In some implementations, the controller 224 can be configured to operate in modes corresponding to each of the surface modification processes described herein. In each mode, the controller 224 issues instructions to the plasma delivery system 214 that adjusts the flux and energy of the ions in the plasma 234 to achieve the specific surface modification process. In some implementations, the controller 224 can modulate the flux and energy of the plasma 234 depending on the material composition of the workpiece 202 detected by the sensing system 208.

The laser finishing system 220 can modify properties of the surface 212 of the workpiece 202 contained within the small portion 222 using a laser 254 that emits a laser beam 255 on the small portion 222 of the surface 212. The small portion 222 can be a beam spot of the laser beam 255 as the laser beam 255 contacts the surface 212 of the workpiece 202. The small portion 222 is shown to be contained within the localized portion 218. The laser beam 255 can thus pass through the localized portion 218. In some implementations, the small portion 222 can be outside of the localized portion 218.

In one example, the controller 224 can operate the laser 254 in a low-power mode, a medium-power mode, and a high-power mode. In the low-power mode, the laser beam 255 can add heat to the small portion 222 to increase the temperature of the workpiece 202 near the small portion 222. In the medium-power mode, the laser beam 255 can clean the small portion 222 by heating the small portion 222 enough to remove residue, flash or other minor material deformations in the vicinity of the small portion 222. The medium-power mode allows the laser beam 255 to remove deformations that may have occurred from, for example, the process used to form the workpiece 202 before the workpiece was transferred to the post-processing system 200. In the high-power mode, the laser beam 255 can ablate the small portion 222 to perform a subtractive manufacturing process. The laser beam 255 can vaporize material in the vicinity of the small portion 222 and perform a process such as etching. In some implementations, the controller 224 can operate the laser beam 255 in a curing mode in which the laser beam 255 can add sufficient heat or energy to finish a curing process of material in the small portion 222. In other implementations, the controller 224 can modulate the power delivered to the laser beam 255 depending on the material composition of the workpiece 202 detected by the sensing system 208.

The plasma delivery system 214 thus serves as an area power source that emits plasma 234 to modify an area defined by the localized portion 218, and the laser finishing system 220 is a point power source that emits the laser beam 255 to modify a point defined by the small portion 222. The coils 250, when charged, define the area of the localized portion 218 within which the plasma 324 is confined. The area of the localized portion 218 can be between, for example, 1 square centimeters and 1000 square centimeters. In some cases, as the area of the localized portion 218 increases, a density of the plasma 234 within the area can decrease. The small portion 222, approximated as a point on the workpiece 202 contacted by the laser beam 255, can have an area between, for example, 0.0001 square millimeters and 20 square millimeters. In some cases, the small portion 222 can be have an elliptical or circular shape. In some implementations, the ratio of the area of the localized portion 218 to the area of the small portion 222 is between, for example, 5:1 and 10⁶:1 or more.

In some implementations, instead of or in addition to the laser 254, finishing system 220 can include a focused ion beam system to generate a focused ion beam (e.g., the beam 255) to mill the surface 212 of the workpiece 202. The workpiece 202 can be, for example, microelectromechanical systems (MEMS) that can have features that can be achieved through milling or etching by the focused ion beam. The finishing system 220, and thus the focused ion beam system, can be positioned to generate the focused ion beam that passes through the localized region above the localized portion 218, and more specifically in some cases, the small portion 222. In such an example, the focused ion beam can make smaller area modifications. As a result, the small portion 222 can be between, for example, several nanometers and 100 nanometers.

To sense and modify different portions of the workpiece 202, the sensing system 208, the plasma delivery system 214, and the laser finishing system 220 can include movable robots 256, 258, and 260, respectively, to control the position of the systems 208, 214, and 220. The controller 224 can control the robot 256 so that the sensing system 208 can detect surface properties of the workpiece 202 at different portions (e.g., the small portion 210) along the surface 212 of the workpiece 202. The controller 224 can control the robot 258 so that the plasma delivery system 214 can delivery plasma to different portions (e.g., the localized portion 218) along the surface 212 of the workpiece 202. The controller 224 can also control the robot 260 so that the robot 260 can perform laser finishing at different portions (e.g., the small portion 222) along the surface 212 of the workpiece 202. In some implementations, the plasma confinement system 216 can be moved with the plasma delivery system 214 to control a location of the localized portion 218 along the surface 212. In other implementations, a robot moves the plasma confinement system 216 while the plasma delivery system 214 is kept stationary. As the controller 224 manipulates the robot, the robot can position the workpiece 202 such that the volume 248 is between the workpiece 202 and the conduit 240.

The robots 256, 258, and 260 are six-axis robots. The robots 256, 258, and 260 therefore can move the sensing system 208, the plasma delivery system 214, and the laser finishing system 220, respectively along any axis (e.g., x-axis, y-axis, and z-axis). The robots 256, 258, and 260 can also rotate the systems 208, 214, and 220 about any axis. As a result, the robots 256, 258, 260 can each move in an x-direction, y-direction, and z-direction and can each rotate in a θ-direction, a Φ-direction, and ψ-direction. The robots 256, 258, 260 can move each of the sensing system 208, the plasma delivery system 214, and the laser finishing system 220 relative to the workpiece 202.

Various combinations of the robots 206, 256, 258, and 260 can be included in the post-processing system 200 to achieve relative movement of the workpiece 202 and the sensing system 208, the plasma delivery system 214, and the laser finishing system 220. In some implementations, the workpiece 202 can be held stationary while the robots 256, 258, and 260 move the sensing system 208, the plasma delivery system 214, and the laser finishing system 220, respectively. In such an example, the workpiece 202 can be held in place by a stationary support or platen. In other implementations, the workpiece robot 206 moves the workpiece 202 while the systems 208, 214, and 220 are held stationary. Thus, in these implementations, one or more six-axis robots (e.g., the workpiece robot 206 or one or more of the robots 256, 258, and 260) can manipulate at least one of the support holding the workpiece and the sensing system 208, the plasma delivery system 214, and/or the laser finishing system 220 to manipulate relative positioning of the workpiece 202 and the sensing system 208, the plasma delivery system 214, and/or the laser finishing system 220.

While individual robots 256, 258, and 260 have been described to control each of the systems 208, 214, 220, in some implementations, the XPS 228 and/or the laser 254 can generate beams 232, 255 that are collinear with the conduit 240. As a result, the laser finishing system 220 and the sensing system 208 can be movable with the plasma delivery system 214. In this example, the controller 224 can manipulate a single robot (e.g., the robot 258) to move the systems 208, 214, 220. The small portion 210 and the small portion 222 can coincide with one another. The small portion 210 and the small portion 222 can further be contained within the localized portion 218. The controller 224 can independently operate the systems 208, 214, 220. The controller 224 may operate the systems 208, 214, 220 simultaneously such that the post-processing system 200 can perform sensing, laser finishing, and/or sputtering at the same time.

While the robots 206, 256, 258, and 260 have each been described to be six-axis robots, the system includes only the robot 206, and the systems 208, 214, 220 are fixed. Alternatively, in some cases, the robots 206 can have less than six-axis control, but the robots 256, 258, and 260 can include several single-axis or multiple-axis actuators that, in combination with the robot 206, provide six-axis control of the relative position of the workpiece to the systems 208, 214, 220. The beam 232 generated by the sensing system 208, the beam 255 of the laser finishing system 220, the inductive coil 246 of the plasma delivery system 214, and the inductive coil 250 of the plasma confinement system 216 may be positioned relative to one another to simplify the foregoing processes. In some implementations, the inductive coils 246, 250 can be positioned such that longitudinal axes of the coils 246, 250 are parallel. In some cases, the inductive coils 246, 250 are coaxial. The inductive coil 246, 250 can be coaxial with the conduit 240. As a result of these implementations, the plasma 234 can be accelerated toward a center of the volume 248 in which the plasma 234 is confined after the plasma 234 exits the conduit 240. In some cases, the inductive coils 246, 250 can also be coaxial with the beam 232 and/or the beam 255. In such cases, the plasma 234 and the beams 232, 255 can be directed to similar or coincident portions of the workpiece 202.

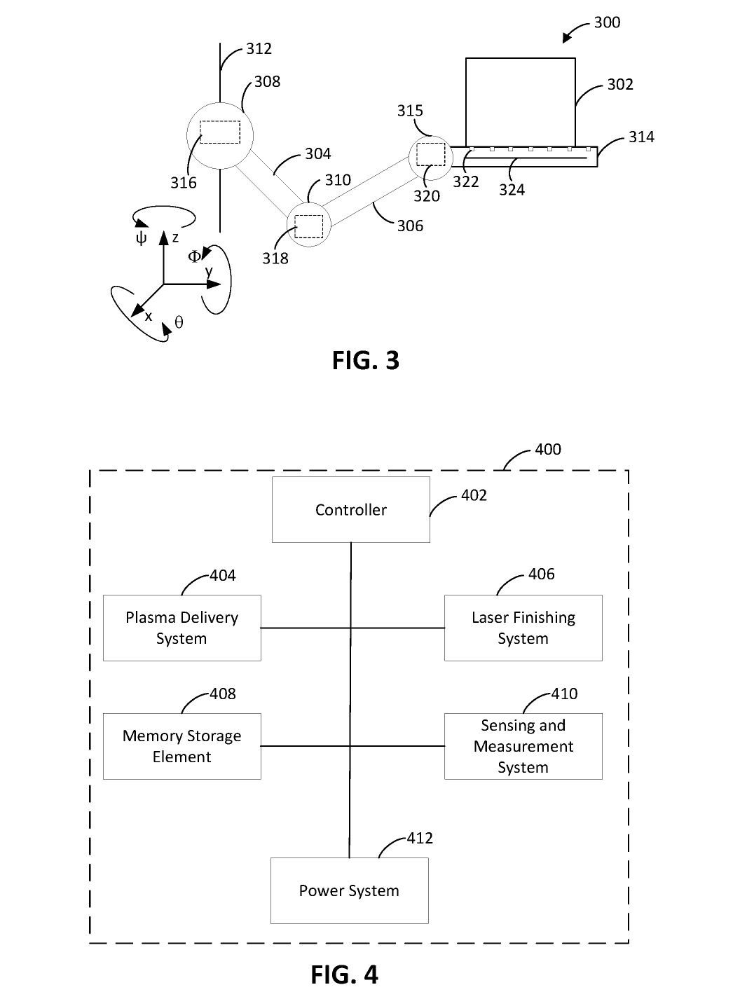

An exemplary robot 300 (e.g., the workpiece robot 206 of FIG. 2), as shown in FIG. 3, holds and manipulates a workpiece 302. As described herein, a controller (e.g., the controller 102) can control the robot 300 based on commands generated by, for example, a CAD system of the controller.

The robot 300 includes a kinematic system having several degrees of freedom to move the workpiece 302 around an environment. For example, the robot 300 includes linkages 304, 306 connected at a joint 310. The linkage 304 is further connected at a joint 308 that is pinned to a chassis 312 of the robot 300. The kinematic system further includes a blade 314 connected to the linkage 306 at a joint 315. The linkages 304, 306, and the blade 314 can each rotate independently of one another to move the workpiece 302 in space. Drives 316, 318, and 320 of the kinematic system located at the joints 308, 310, and 315, respectively, can control rotation of the linkages 304, 306, and the blade 314, respectively. For example, the drives 316, 318, 320 can rotate the linkages 304, 306, and the blade 314 in a θ-direction, a Φ-direction, and ψ-direction and thus can move the workpiece 302 in an x-direction, y-direction, and z-direction and rotate the workpiece 302 in a θ-direction, a Φ-direction, and ψ-direction.

The blade 314 can support and hold the workpiece 302. The blade 314 can include vacuum holes 322 that operate as part of a vacuum system that pulls the workpiece 302 toward the blade 314 as the robot 300 moves the workpiece 302 around in space.

In some cases, maintaining the workpiece 302 at an elevated temperature allows the workpiece 302 to be more easily processed using, for example, a post-processing system (e.g., the post-processing system 106 of FIG. 1 and the post-processing system 200 of FIG. 2). The blade 314 can further include a resistive heater 324 to heat the workpiece 302 as the robot 300 holds the workpiece 302. For example, the elevated temperature can continue a curing process in the workpiece 302 initiated before the robot 300 received the workpiece 302.

The robot 300 can function to hold, support, and otherwise manipulate the workpiece 302 during various processes of a part manufacturing system (e.g., the part manufacturing system 100 of FIG. 1). The robot 300 can be a substrate transfer mechanism to move the workpiece 302 between various systems of the part manufacturing system, such as, for example between a 3D printing system and a post-processing system (e.g., the post-processing system 200 of FIG. 2). The robot 300 can be a workpiece robot to manipulate the workpiece 302 during post-processing of the workpiece 302 (e.g., the workpiece robot 206 of FIG. 2). The robot 300 can, in some cases, serve as both the substrate transfer mechanism and the workpiece robot. For example, after the robot 300 has transported the workpiece 302 from the 3D printing system to the post-processing system, the robot 300 can continue to move the workpiece 302 as the post-processing system executes various processes described herein to modify the workpiece 302.

An exemplary control system 400 for a post-processing system (e.g., the post-processing system 106 of FIG. 1 or the post-processing system 200 of FIG. 2) includes a controller 402 to operate a plasma delivery system 404, a laser finishing system 406, a memory storage element 408, a sensing and measurement system 410, and a power system 412. The controller 402 can be a single controller that operates the systems of the control system 400. In some implementations, each of the plasma delivery system 404, the laser finishing system 406, the sensing and measurement system 410, and the power system 412 can include separate controllers that receive instructions from the controller 402. The power system 412 can include power sources operable with each of the plasma delivery system 404, the laser finishing system 406, the memory storage element 408, and the sensing and measurement system 410. The control system 400 generates and executes instructions to modify a workpiece (e.g., the workpiece 202 of FIG. 2).

The plasma delivery system 404 (e.g., the plasma delivery system 214 of FIG. 2) can receive instructions from the controller 402 to execute a specific mode of sputtering on localized portions of the workpiece. The controller 402 can instruct the plasma delivery system 404 to, for example, modify a hardness, a texture, a roughness, a chemical composition, or other material property of the workpiece. The instructions may cause the power system 412 to modulate the power source associated with the plasma delivery system 404. In some cases, the power source may be electrically connected to inductive coils of the plasma delivery system 404. In some implementations, the power source may be electrically connected to conductors or electrodes of the plasma delivery system 404. The controller 402 can further control valves of the plasma delivery system 404 to modify an amount of gas released into the plasma delivery system 404. In some cases, the controller 402 may control a plasma confinement system as part of controlling the plasma delivery system 404. For example, the controller 402 can control electrical energy delivered to inductive coils of the plasma confinement system.

The laser finishing system 406 (e.g., the laser finishing system 220 of FIG. 2) can receive instructions from the controller 402 to operate in various modes to modify portions of the workpiece smaller than the portions modified by the plasma delivery system 404. The laser finishing system 406 can operate in a low-power mode, a medium-power mode, a high-power mode, and a curing mode, as described herein. The power system 412 can thus modulate the power source associated with the laser finishing system 406 to allow a laser to generate a beam at different powers and frequencies according to the mode in which the laser finishing system 406 is operating.

The sensing and measurement system 410 (the sensing system 208 of FIG. 2) can receive instructions from the controller 402 to detect properties of the workpiece. For example, as described herein, the sensing and measurement system 410 can detect surface roughness, chemical composition, and other appropriate properties of the workpiece.

The controller 402 can receive instructions from a CAD system (e.g., the CAD system of the controller 102 of FIG. 1) to control each of the systems of the control system 400. For example, the controller 402 can receive data indicative of gross geometry from the CAD system that corresponds to the geometry of the workpiece when the workpiece is transferred into the post-processing system. The controller 402 can further receive data indicative of detailed geometry from the CAD system that the workpiece does not include because, for example, the resolution of the 3D printing system or the fabrication system for the workpiece was unable to achieve the features specified. Based on the data indicative of the detailed geometry, the controller 402 can issue instructions to each of the plasma delivery system 404 and the laser finishing system 406 to incorporate the detailed geometry into the workpiece. In some cases, the controller 402 can receive data from the CAD system and store the data within the memory storage element 408.

The memory storage element 408 can include various parameters for specific modes of each of the plasma delivery system 404, the laser finishing system 406, the sensing and measurement system 410, and the power system 412. As a result, when the controller 402 transmits instructions for a particular mode of operation (e.g., the low-power, medium-power, and high-power modes of the laser finishing system 406), the instructions may include parameters (e.g., laser power or frequency, AC power or frequency) that the systems 404, 406, 410, and 412 can use to achieve the objectives (e.g., heat addition, ablation) of those modes.

The controller 402 can work with the sensing and measurement system 410 can cooperate with the controller 402 to generate instructions to transmit to the plasma delivery system 404 and the laser finishing system 406. For example, the sensing and measurement system 410 may detect surface defects on the workpiece that may not part of the data indicative of the detailed geometry as described herein. The controller 402 may generate instructions to remove the surface defects and then transmit the instructions to the plasma delivery system 404 or the laser finishing system 406 to remove the defects.

In other cases, as the plasma delivery system 404 and the laser finishing system 406 operate, the sensing and measurement system 410 can monitor the surface of the workpiece to make sure that the plasma delivery system 404 and the laser finishing system 406 are accurately achieving the detailed geometries. For example, the sensing and measurement system 410 may monitor the actual geometry, the roughness, the texture, or other properties produced by each of the plasma delivery system 404 and the laser finishing system 406.

The systems and all of the related functional operations described herein can be implemented in digital electronic circuitry, or in computer software, firmware, or hardware, including the structural means disclosed in this specification and structural equivalents thereof, or in combinations of them. The systems and methods can be implemented as one or more computer program products, i.e., one or more computer programs tangibly embodied in an information carrier, e.g., in a non-transitory machine readable storage medium or in a propagated signal, for execution by, or to control the operation of, data processing apparatus, e.g., a programmable processor, a computer, or multiple processors or computers. A computer program (also known as a program, software, software application, or code) can be written in any form of programming language, including compiled or interpreted languages, and it can be deployed in any form, including as a standalone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub programs, or portions of code). A computer program can be deployed to be executed on one computer or on multiple computers at one site or distributed across multiple sites and interconnected by a communication network.

The processes and logic flows described herein can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

A number of implementations have been described. Nevertheless, it will be understood that various modifications may be made. Accordingly, other implementations are within the scope of the following claims.

What is claimed is:

1. An apparatus for surface modification, comprising:
a support to hold a workpiece;
a plasma source to generate a plasma in a localized region that is smaller than the workpiece; and
a robot coupled to at least one of the support and the plasma source to provide six-axis control of relative positioning of the workpiece and the plasma source.

2. The apparatus of claim 1, comprising a vacuum chamber, wherein the support, the plasma source, and the robot are positioned in the vacuum chamber.

3. The apparatus of claim 1, comprising a laser positioned to generate a laser beam that passes through the localized region.

4. The apparatus of claim 3, wherein a beam spot of the laser beam on an exposed surface of the workpiece is smaller than a portion of the workpiece impinged by the plasma.

5. The apparatus of claim 1, comprising a focused ion beam system positioned to generate a focused ion beam that passes through the localized region.

6. The apparatus of claim 5, wherein a beam spot of the focused ion beam on an exposed surface of the workpiece is smaller than a portion of the workpiece impinged by the plasma.

7. The apparatus of claim 1, wherein the plasma source comprises a tube, a gas source to inject a gas into the tube, a first radio frequency (RF) power source, and a first plurality of conductive coils surrounding the tube and coupled to the first RF power source.

8. The apparatus of claim 7, comprising a second radio frequency (RF) power source, and a second plurality of conductive coils coupled to the second RF power source, the second plurality of coils positioned to surround a volume in which the plasma is emitted from the tube.

9. The apparatus of claim 8, comprising a controller configured to cause the robot to position the workpiece such that the volume is between the workpiece and the tube.

10. The apparatus of claim 8, wherein the first and second plurality of coils are oriented along parallel axes.

11. A method of surface modification, comprising:
generating a plasma adjacent to a workpiece in a localized region that is smaller than the workpiece such that ions from the plasma impinges only a portion of an exposed surface of the workpiece.

12. The method of claim 11, wherein ions from the plasma are deposited onto the portion of the exposed surface.

13. The method of claim 11, wherein ions from the plasma etch the portion of the exposed surface.

14. The method of claim 13, comprising impinging the portion of the exposed surface with a laser beam simultaneous with generating the plasma.

15. The method of claim 14 wherein the laser beam heats the exposed surface without removing material from the exposed surface.

16. The method of claim 14, wherein the laser beam ablates material from the exposed surface.

17. The method of claim 11, comprising constraining the plasma with a coil positioned to surround a volume between a plasma source and the workpiece.

18. The method of claim 11, further comprising milling the portion of the exposed surface with a focused ion beam simultaneous with generating the plasma.

19. A manufacturing system, comprising:
a 3D printer configured to fabricate a workpiece;
an apparatus for surface modification, the apparatus comprising:
a support to hold a workpiece,
a plasma source to generate a plasma in a localized region that is smaller than the workpiece, and
a six-axis robot coupled to at least one of the support and the plasma source to manipulate relative positioning of the workpiece and the plasma source; and
a transport system to move the workpiece from the additive manufacturing system to the support in the apparatus for surface modification.

20. A method of manufacturing a part, comprising:
fabricating a workpiece by 3D printing; and
applying ions to a selected portion of an exposed surface of the fabricated workpiece by generating a plasma adjacent to a workpiece in a localized region that is smaller than the workpiece.
